(19) United States
(12) Patent Application Publication
(10) Pub. No.: US 2026/0186182 A1
(43) Pub. Date: Jul. 2, 2026

(54) OPTICAL FILM AND ELECTRONIC DEVICE INCLUDING THE SAME

(71) Applicant: Samsung Display Co., LTD., Yongin-si (KR)

(72) Inventors: JIEUN NAM, Yongin-si (KR); MINHYUCK KANG, Yongin-si (KR)

(21) Appl. No.: 19/385,394

(22) Filed: Nov. 11, 2025

(30) Foreign Application Priority Data
Dec. 26, 2024 (KR) 10-2024-0197216

(51) Int. Cl. G02B 5/20

(52) U.S. Cl. CPC G02B 5/201

(57) ABSTRACT

An optical film includes a base portion and a plurality of protrusion portions disposed on one surface of the base portion. Each of the protrusion portions includes a first portion extending in a first direction parallel to a thickness direction of the base portion, and a second portion connected to the first portion and extending at a first inclination angle with respect to the first direction, where the first inclination angle is an acute angle.

This application claims priority to Korean Patent Application No. 10-2024-0197216, filed on Dec. 26, 2024, and all the benefits accruing therefrom under 35 U.S.C. § 119, the content of which in its entirety is herein incorporated by reference.

### BACKGROUND

### 1. Field

The present disclosure relates to an optical film and an electronic device including the optical film. More particularly, the present disclosure relates to an optical film including a base portion and a protrusion portion and an electronic device including the optical film.

### 2. Description of Related Art

Various types of electronic devices are widely used to provide image information in various fields, and recently, electronic devices including an edged display module, a curved display module, or a foldable display module are being developed.

The electronic device including the display module may have varying brightness levels across its display surface depending on the angle at which a user views the electronic device, resulting in a deterioration of display quality. Accordingly, research is being conducted to add optical films with various functions on top of the display module to reduce deterioration in the display quality according to the viewing angle.

### SUMMARY

The present disclosure provides an optical film to improve viewing-angle characteristics of an electronic device.

The present disclosure provides an electronic device with improved brightness non-uniformity, reduced color difference, and improved viewing-angle characteristics using a protrusion portion included in the optical film.

Embodiments of the invention provide an optical film including a base portion and a plurality of protrusion portions disposed on one surface of the base portion. In such embodiments, each of the protrusion portions includes a first portion extending in a first direction parallel to a thickness direction of the base portion and a second portion connected to the first portion and extending at a first inclination angle with respect to the first direction, and the first inclination angle is an acute angle.

In an embodiment, each of the first portion and the second portion may have a stripe shape extending in one direction on a plane parallel to the one surface of the base portion.

In an embodiment, the optical film may further include a filling portion filled in a space between the protrusion portions.

In an embodiment, each of the protrusion portions may include an outer portion and a core portion surrounded by the outer portion, and the core portion may be filled with an air.

In an embodiment, the optical film may further include a cover layer disposed at at least one selected from upper and lower sides of the base portion, the protrusion portions may have a first refractive index, and the cover layer may have a second refractive index different from the first refractive index.

In an embodiment, a difference between the first refractive index and the second refractive index may be greater than or equal to about 0.1 and less than or equal to about 2.

Embodiments of the invention provide an optical film including a base portion having a thickness in a first direction and a pattern portion including a plurality of protrusion portions disposed on one surface of the base portion and spaced apart from each other in a second direction different from the first direction. In such embodiments, each of the protrusion portions includes a first portion having a trapezoidal shape in a transverse cross-section and extending in the first direction and a second portion having a rectangular shape in the transverse cross-section, connected to the first portion, and extending at a first inclination angle with respect to a direction in which the first portion extends. In such embodiments, the first inclination angle is an acute angle.

In an embodiment, a length of a lower surface of the first portion may be smaller than a length of a side surface of the first portion when viewed in the transverse cross-section.

In an embodiment, a length of a lower surface of the second portion connected to the first portion may be smaller than a length of a side surface of the second portion in a direction away from the first portion when viewed in the transverse cross-section.

In an embodiment, a ratio of a length of a side surface of the second portion to a length of a side surface of the first portion is in a range from about 1:1 to about 10:1 when viewed in the transverse cross-section.

In an embodiment, a sum of a length of a side surface of the first portion and a length of a side surface of the second portion may be greater than or equal to about 1 micrometer (μm) and smaller than or equal to about 50 μm when viewed in the transverse cross-section.

In an embodiment, a separation distance in the second direction between the protrusion portions may be greater than or equal to about 0.5 μm and smaller than or equal to about 5 μm when viewed in the transverse cross-section.

In an embodiment, the first inclination angle may be in a range from about 1° to about 60° when viewed in the transverse cross-section.

Embodiments of the invention provide an electronic device including a display module including a main display surface and a sub-display surface providing an image in a direction different from a direction of an image provided by the main display surface, an optical film disposed on the display module, and a window disposed on the optical film. In such embodiments, the optical film includes a base portion defining at least one selected from upper and lower surfaces of the optical film and a plurality of protrusion portions arranged on the base portion. In such embodiments, each of the protrusion portions includes a first portion extending in a first direction parallel to a thickness direction of the base portion and a second portion connected to the first portion and extending at a first inclination angle with respect to the first direction, and the first inclination angle is an acute angle.

In an embodiment, the optical film may be arranged to correspond to sub-display surface.

In an embodiment, the second portion of each of the protrusion portions may extend from the first portion to the direction of the image provided by the main display surface.

In an embodiment, the sub-display surface may have a curved surface convex to the direction in which the image thereof is provided.

In an embodiment, the base portion of the optical film, which is arranged to correspond to the sub-display surface, may have a curved shape corresponding to the curved surface of the sub-display surface.

In an embodiment, each of the first portion and the second portion may have a stripe shape extending in one direction on a plane parallel to one surface of the base portion.

In an embodiment, the electronic device further comprises at least one selected from a processor, a memory, and a power module.

According to embodiments of the invention, as described herein, the optical film includes plural protrusion portions each having a bent shape at a selected inclination angle to change a path of light provided thereto, and thus, the display quality of the electronic device including the optical film is improved.

According to embodiments of the invention, as the electronic device includes the optical film provided with the plural protrusion portions that change the light path, the brightness non-uniformity between the main display surface and the sub-display surface is improved. Accordingly, a phenomenon in which a dark portion appears at a boundary between the main display surface and the sub-display surface is reduced. In addition, in the electronic device, a color difference between the main display surface and the sub-display surface is reduced. As a result, the electronic device has improved viewing angle characteristics.

### BRIEF DESCRIPTION OF THE DRAWINGS

FIG. 1A is a block diagram showing an electronic device according to an embodiment of the present disclosure;

FIG. 1B is a view showing electronic devices according to embodiments of the present disclosure;

FIG. 2A is a perspective view showing an electronic device according to an embodiment of the present disclosure;

FIG. 2B is a perspective view showing an electronic device according to an embodiment of the present disclosure;

FIG. 2C is a perspective view showing an electronic device according to an embodiment of the present disclosure;

FIG. 3 is an exploded perspective view showing an electronic device according to an embodiment of the present disclosure;

FIG. 4 is a cross-sectional view showing the electronic device shown in FIG. 3;

FIG. 5 is a perspective view showing an optical film according to an embodiment of the present disclosure;

FIG. 6 is a plan view showing an optical film according to an embodiment of the present disclosure;

FIG. 7 is a cross-sectional view showing an optical film according to an embodiment of the present disclosure;

FIG. 8 is a perspective view showing an optical film according to an embodiment of the present disclosure;

FIG. 9 is a cross-sectional view showing an optical film according to an embodiment of the present disclosure;

FIG. 10 is a cross-sectional view showing an optical film according to an embodiment of the present disclosure;

FIG. 11 is a cross-sectional view showing an optical film according to an embodiment of the present disclosure;

FIG. 12 is a cross-sectional view showing an electronic device according to an embodiment of the present disclosure;

FIG. 13 is a cross-sectional view showing a portion of an electronic device according to an embodiment of the present disclosure;

FIG. 14 is a graph showing results of evaluating viewing angle characteristics of an electronic device according to an embodiment of the present disclosure and an electronic device according to a comparative example; and

FIG. 15 is a graph showing results of evaluating viewing angle characteristics of an electronic device according to an embodiment of the present disclosure and an electronic device according to a comparative example.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

In the present disclosure, it will be understood that when an element (or area, layer, or portion) is referred to as being “connected to” or “coupled to” another element or layer, it can be directly connected or coupled to the other element or layer or intervening elements or layers may be present therebetween.

Like numerals refer to like elements throughout. In the drawings, the thickness, ratio, and dimension of components are exaggerated for effective description of the technical content.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of an optical film and an electronic device according to the present disclosure will be described in detail with reference to the accompanying drawings.

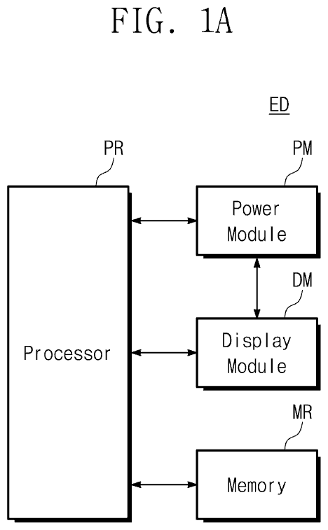

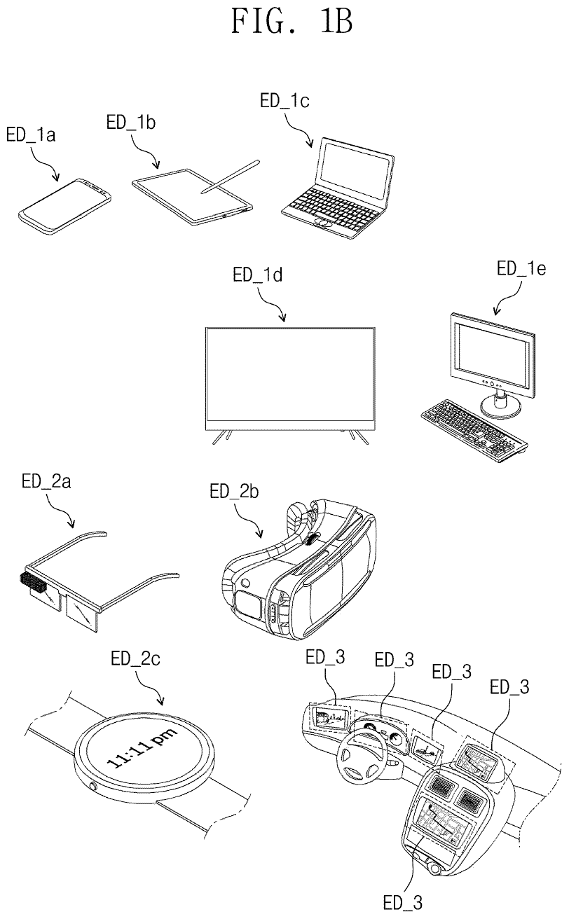

FIG. 1A is a block diagram of an electronic device according to an embodiment of the present disclosure. Referring to FIG. 1A, an embodiment of the electronic device ED may include a display module DM, a processor PR, a memory MR, and a power module PM.

The processor PR may include at least one selected from a central processing unit (CPU), an application processor (AP), a graphics processing unit (GPU), a communication processor (CP), an image signal processor (ISP), and a controller.

The memory MR may store data information used for the operation of the processor PR or the display module DM. When the processor PR executes applications stored in the memory MR, an image data signal and/or an input control signal may be transmitted to the display module DM, and the display module DM may process the received signals to output image information through a display screen.

The power module PM may include a power supply module, such as a power adapter or a battery device, and a power conversion module that converts power supplied by the power supply module to generate power used for the operation of the electronic device ED.

At least one of components of the electronic device ED may be included in a display device according to embodiments. In addition, among individual modules that are functionally included within a single module, some may be included in the display device while others may be provided separately from the display device. in an embodiment, for example, the display device may include the display module DM described later. The processor PR, the memory MR, and the power module PM may not be provided within the display device, instead, they may be provided in the form of other devices within the electronic device ED.

FIG. 1B is a view showing electronic devices according to embodiments of the present disclosure.

Referring to FIG. 1B, various electronic devices to which the display device according to embodiments is applied may include an electronic device that displays images, such as a smartphone ED_1a, a tablet personal computer (PC) ED_1b, a laptop computer ED_1c, a television ED_1d, a desktop monitor ED_1e, etc., a wearable electronic device including a display module, such as a smart glasses ED_2a, a head-mounted display ED_2b, a smartwatch ED_2c, etc., or an in-vehicle electronic device ED_3 including a display module, such as an instrument panel, a center fascia, a dashboard-mounted center information display (CID), or a room mirror display.

The display device according to an embodiment may be applied to various electronic devices. The electronic device may further include modules or devices with additional functions in addition to the display device.

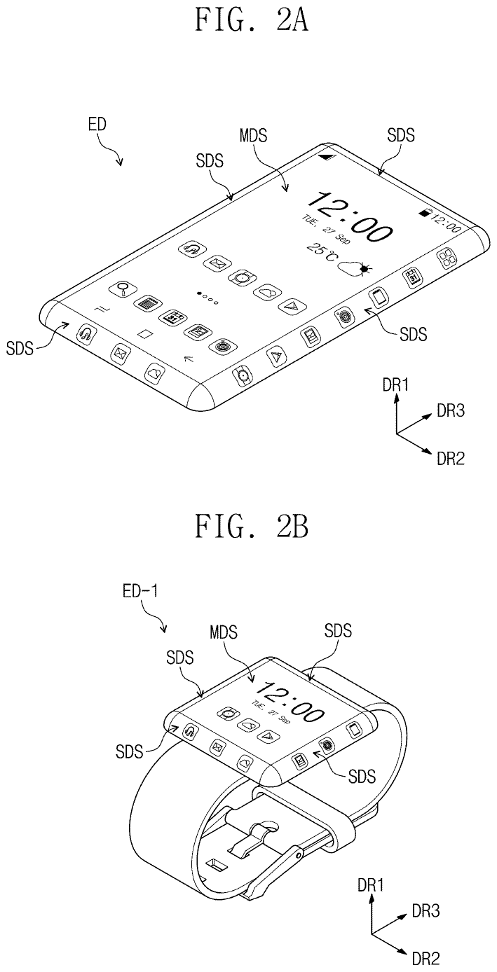

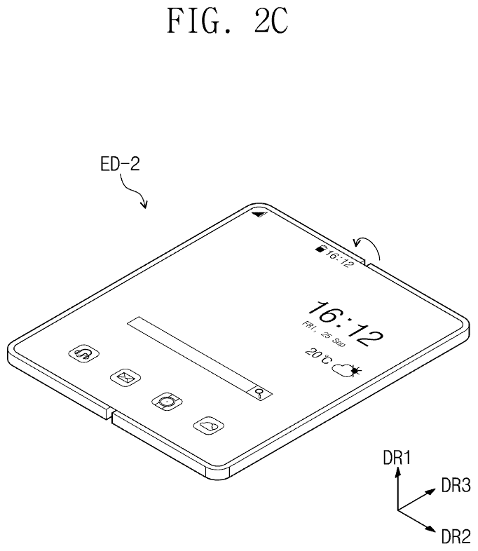

FIGS. 2A to 2C are perspective views of electronic devices according to embodiments of the present disclosure. In an embodiment, an electronic device may be activated in response to electrical signals. FIG. 2A shows a mobile phone with an edge display surface as an embodiment of an electronic device ED, FIG. 2B shows a smartwatch with an edge display surface as an embodiment of an electronic device ED-1, and FIG. 2C shows a foldable mobile phone as an embodiment of an electronic device ED-2.

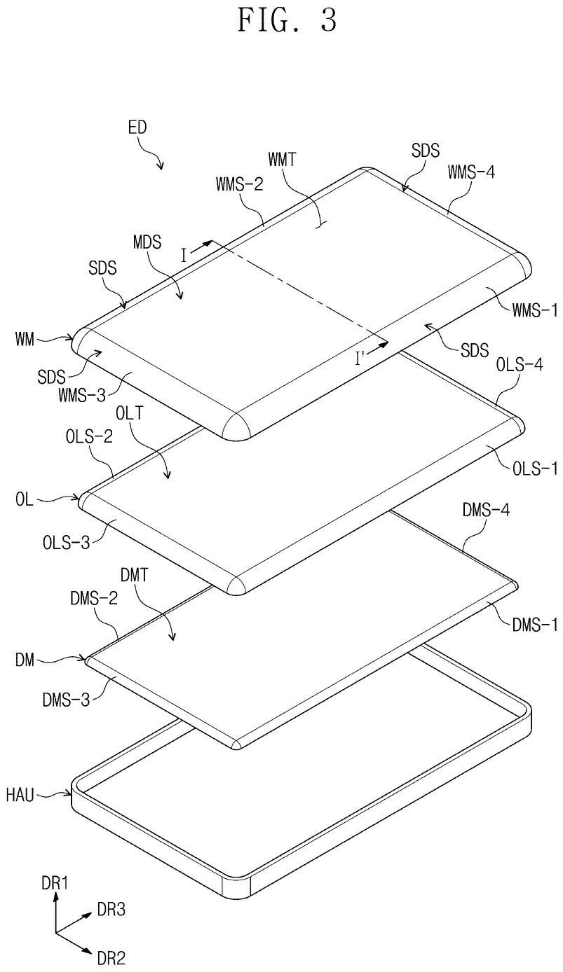

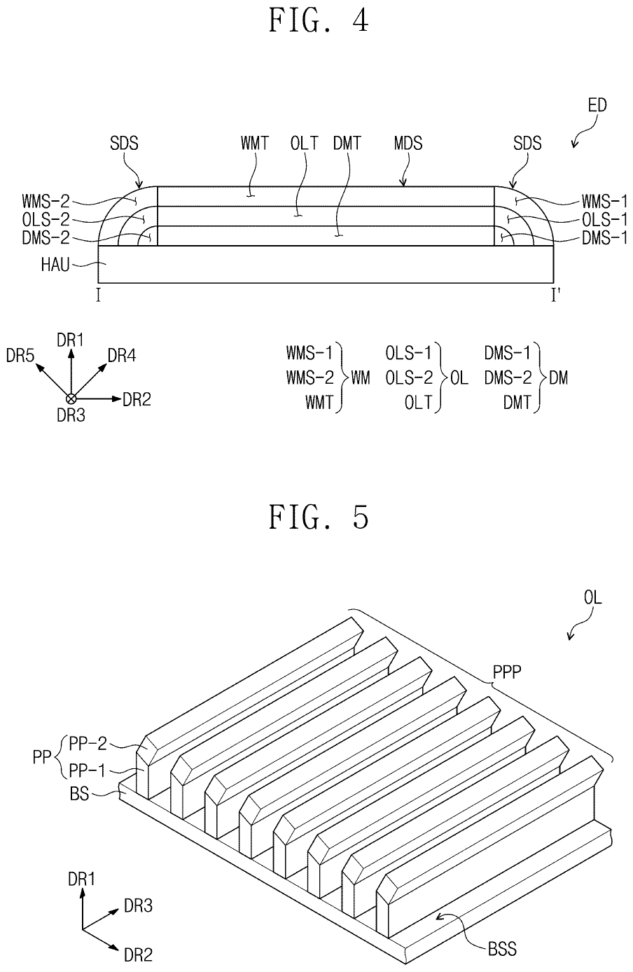

FIG. 3 is an exploded perspective view of the electronic device ED according to an embodiment of the present disclosure, and FIG. 4 is a cross-sectional view of the electronic device ED shown in FIG. 3. FIG. 3 is an exploded perspective view of the electronic device ED shown in FIG. 2A. FIG. 4 is a cross-sectional view taken along line I-I′ of FIG. 3.

Embodiments of the electronic device ED, ED-1, and ED-2 shown in FIGS. 2A to 2C are merely examples, and such embodiments of the electronic devise may be applied to a large-sized electronic device, such as a television, a monitor, an outdoor billboard, etc., and a small and medium-sized electronic device, such as a personal computer, a notebook computer, a personal digital assistant, a car navigation unit, a game unit, a tablet computer, a smartwatch, a camera, etc.

Embodiments of the electronic device ED, ED-1, and ED-2 described with reference to FIGS. 2A to 2C may include the display device that includes display module DM to display the image.

Hereinafter, embodiments of the electronic device ED shown in FIG. 2A will be mainly described for convenience of description, an optical film and the electronic device including the optical film according to embodiments described hereinafter may be equally applied to various other types of electronic device.

In the accompanying drawings, first, second, third, fourth, and fifth directional axes DR1, DR2, DR3, DR4, and DR5 are shown. The first, second, third, fourth, and fifth directional axes DR1, DR2, DR3, DR4, and DR5 described in the present disclosure may be relative to each other and may be changed to other directions. In addition, directions indicated by the first, second, third, fourth, and fifth directional axes DR1, DR2, DR3, DR4, and DR5 may be referred to as first, second, third, fourth, and fifth directions DR1, DR2, DR3, DR4, and DR5 and may be assigned with the same reference numerals. In the present disclosure, the second directional axis DR2 may be perpendicular to the third directional axis DR3, and the first directional axis DR1 may be a normal line direction with respect to a plane defined by the second directional axis DR2 and the third directional axis DR3. In addition, the fourth directional axis DR4 may be a direction between the first direction DR1 and the second direction DR2, and the fifth directional axis DR5 may be a direction between a direction opposite to the second direction DR2 and the first direction DR1.

The electronic device ED may include the display module DM with multiple display portions that provide the image in different directions. The display module DM may include an upper display module portion DMT, which provides the image to a main display surface MDS in a front direction, and side display module portions DMS-1 to DMS-4, which provide the image to a sub-display surface SDS in directions different from the front direction. The upper display module portion DMT may display the image toward a direction corresponding to the first directional axis DR1 perpendicular to each of the second directional axis DR2 and the third directional axis DR3. Referring to FIG. 4, a direction in which a first side display module portion DMS-1 faces may correspond to the fourth direction DR4. In addition, a direction in which a second side display module portion DMS-2 faces may correspond to the fifth direction DR5.

In the present disclosure, an upper surface (or a front surface) and a lower surface (or a rear surface) of each component may be defined with respect to the direction to which the upper display module portion DMT displays the image. The upper and lower surfaces may be opposite to each other in the first directional axis DR1, and a normal line direction with respect to each of the front surface and the rear surface may be substantially parallel to the first directional axis DR1.

In the following descriptions, the expression “when viewed in a plane” or “in plan view” may refer to a state of being viewed in the first direction DR1. The first direction DR1 may be a thickness direction of the electronic device ED. Directions indicated by the first, second, third, fourth, and fifth directions DR1, DR2, DR3, DR4, and DR5 may be relative to each other and may be changed to other directions.

Referring to FIGS. 3 and 4, an embodiment of the electronic device ED may include the display module DM and the optical film OL disposed on the display module DM. The electronic device ED may include a lower substrate HAU accommodating the display module DM. In addition, the electronic device ED may include a window WM disposed above the optical film. The lower substrate HAU may include a quadrangular frame on its sides and a flat bottom surface. However, the shape of the lower substrate HAU should not be limited thereto or thereby, and the shape of the lower substrate HAU may be changed according to the shape of the display module DM accommodated therein and the window WM (or an upper substrate) coupled thereto. The electronic device ED may have a stack structure of the lower substrate HAU, the display module DM, the optical film OL, and the window WM.

The display module DM may include the upper display module portion DMT parallel to the lower substrate HAU and the side display module portions DMS-1 to DMS-4, each disposed at one side of the upper display module portion DMT in four directions. In addition, different from the side display module portions DMS-1 to DMS-4 shown in FIG. 3, one or more of the side display module portions DMS-1 to DMS-4 may be omitted.

The optical film OL may include an upper optical film OLT parallel to the upper display module portion DMT and side optical films OLS-1 to OLS-4, each disposed at one side of the upper optical film OLT in four directions. The window WM may include an upper window portion WMT parallel to the lower substrate HAU and side window portions WMS-1 to WMS-4, each disposed at one side of the upper window portion WMT in four directions.

The electronic device ED may include a first edge, a second edge, a third edge, and a fourth edge. The first edge may include the first side display module portion DMS-1, a first side optical film OLS-1, and a first side window portion WMS-1. The second edge may include the second side display module portion DMS-2, a second side optical film OLS-2, and a second side window portion WMS-2. The third edge may include a third side display module portion DMS-3, a third side optical film OLS-3, and a third side window portion WMS-3. The fourth edge may include a fourth side display module portion DMS-4, a fourth side optical film OLS-4, and a fourth side window portion WMS-4.

In an embodiment, as shown in FIGS. 2A and 3, the electronic device ED includes four edges, e.g., the first edge, the second edge, the third edge, and the fourth edge, but the present disclosure should not be limited thereto or thereby. In another embodiment, for example, the electronic device may include only two edges.

The electronic device ED may include the main display surface MDS and at least one sub-display surface SDS. In such an embodiment, each of the four edges may correspond to the sub-display surface SDS. In an embodiment, as shown in FIGS. 2A and 3, the electronic device ED includes the four edges, but not being limited thereto. In another embodiment, at least one of the edges may be omitted.

The window WM may include a glass substrate and may be used as a cover window of the electronic device ED. The glass substrate included in the window WM may be a tempered glass substrate. In addition, the glass substrate may be an ultra-thin glass.

The optical film OL may be a film that controls light provided from the display module DM. Materials for the optical film OL should not be particularly limited.

The optical film OL may entirely overlap the display module DM or may overlap at least a portion of the display module DM. That is, the optical film OL may cover all or a portion of an upper surface of each of the upper display module portion DMT, the first side display module portion DMS-1, the second side display module portion DMS-2, the third side display module portion DMS-3, and the fourth side display module portion DMS-4.

FIGS. 3 and 4 show an embodiment having the structure in which the optical film OL entirely covers the upper surface of the display module DM. In such an embodiment, the optical film OL may have a shape corresponding to a shape of the display module DM. In addition, the window WM may have a shape corresponding to the shape of the optical film OL.

However, the present disclosure should not be limited thereto or thereby. The optical film OL will be described in detail later.

The display module DM may display the image in response to electrical signals and may transmit and receive information on an external input. Although not shown in figures, the display module DM may include a light emitting element. The light emitting element may be an organic light emitting element including an organic light emitting material or an inorganic light emitting element including quantum dots and quantum rods.

Although not shown in figures, the electronic device ED may further include an adhesive layer. The adhesive layer may be disposed between the display module DM and the optical film OL and may attach the optical film OL to the display module DM.

Hereinafter, an embodiment of the optical film OL will be described in detail with reference to FIGS. 5 to 7.

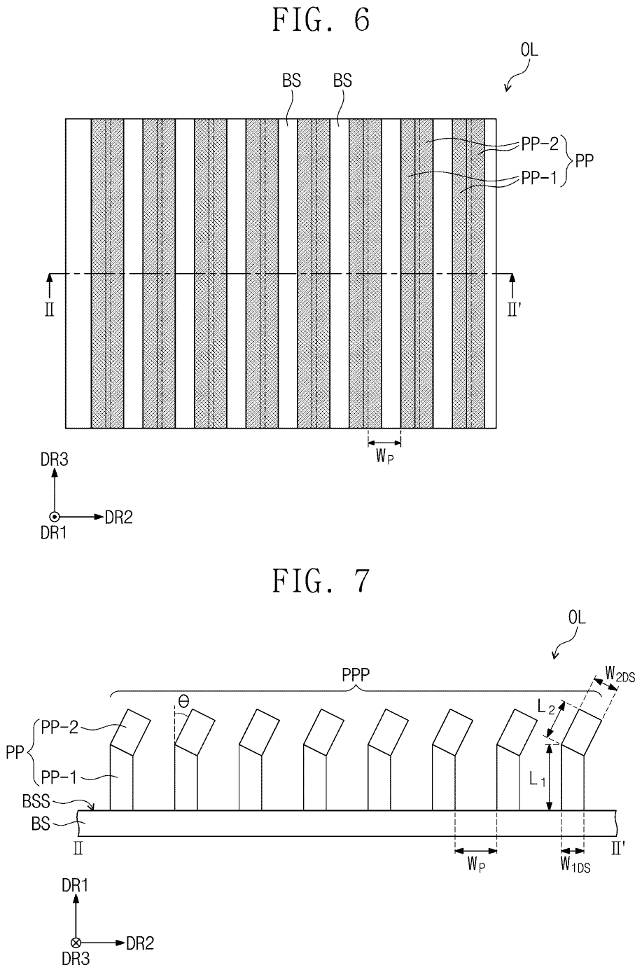

FIG. 5 is a perspective view of the optical film OL according to an embodiment of the present disclosure, FIG. 6 is a plan view of the optical film OL according to an embodiment of the present disclosure, and FIG. 7 is a cross-sectional view of the optical film OL according to an embodiment of the present disclosure. FIG. 7 is a cross-sectional view taken along line II-II′ of FIG. 6.

In FIGS. 5 to 7, for the convenience of illustration and description, the first, second, and third directions DR1, DR2, and DR3 are defined assuming that the optical film OL is the upper optical film OLT (refer to FIG. 4). However, since the optical film OL includes the side optical films OLS-1 to OLS-4 as described above, directions indicated by the first, second, and third directions DR1, DR2, and DR3 may be relative to each other and may be changed to other directions.

Referring to FIG. 5, an embodiment of the optical film OL may include a base portion BS and a plurality of protrusion portions PP disposed on one surface of the base portion BS. Each of the protrusion portions PP may include a first portion PP-1 extending in the first direction DR1 parallel to a thickness direction of the base portion BS and a second portion PP-2 connected to the first portion PP-1 and extending at a first inclination angle θ with respect to the first direction DR1. The first inclination angle θ may be an acute angle. In an embodiment, for example, the first inclination angle may be greater than or equal to about 1 degree and smaller than or equal to about 60 degrees.

The base portion BS may provide a base surface on which the protrusion portions PP are disposed in the optical film OL. The base portion BS may support the protrusion portions PP and may improve durability of the optical film OL.

The base portion BS may have a flat or curved shape. In an embodiment, as shown in FIGS. 5 to 7, the base portion BS has the flat shape, however, the shape of the base portion BS should not be limited thereto or thereby.

The base portion BS may be transparent. The base portion BS may include at least one selected from light transmitting materials such as polycarbonate (PC), polyethylene terephthalate (PET), polymethyl methacrylate (PMMA), and glass, but it should not be limited thereto or thereby.

The protrusion portions PP may be disposed directly on the one surface of the base portion BS. The protrusion portions PP of the optical film OL may be formed by radiating a laser beam onto a base substrate with flat upper and lower surfaces to cause thermal damage to the base substrate and etching the thermally damaged portion through a chemical etching process. In the process of radiating the laser beam, the protrusion portions PP may be formed, and the optical film OL having the base portion BS and the protrusion portions PP may be manufactured. However, the manufacturing method of the optical film OL should not be limited thereto or thereby.

Referring to FIGS. 5 and 6, the first portion PP-1 and the second portion PP-2 of the optical film OL may have a stripe shape extending in one direction on a plane parallel to the one surface BSS of the base portion BS. The one surface BSS of the base portion BS may be in contact with a lower surface of the first portion PP-1. The one direction may be the third direction DR3. Since the protrusion portions PP extend in the third direction DR3, the first portion PP-1 and the second portion PP-2 may extend in the third direction DR3, the protrusion portions PP may be repeatedly arranged in the second direction DR2, and a portion of the base portion BS, which is exposed, may be disposed between the protrusion portions PP. The protrusion portions PP may be repeatedly arranged in the second direction DR2 and may be spaced apart from each other by a separation distance Wp. The separation distance Wp in the second direction DR2 between the protrusion portions PP may be constant (or all be identical) when the base portion BS has the flat surface. The separation distance Wp in the second direction DR2 between the protrusion portions PP may be identical to each other or may differ from one another when the base portion BS has the curved shape.

Referring to FIG. 7, the optical film OL may include the base portion BS having a thickness in the first direction DR1 and a pattern portion PPP including the protrusion portions PP disposed on the base portion BS and spaced from each other in the second direction DR2. Each of the protrusion portions PP may include the first portion PP-1 and the second portion PP-2. The first portion PP-1 may have a trapezoidal shape in a cross-section perpendicular to the base portion BS and may extend in the first direction DR1. The second portion PP-2 may have a rectangular shape in the cross-section perpendicular to the base portion BS, may be connected to the first portion PP-1, and may extend to have the first inclination angle θ with respect to a direction in which the first portion PP-1 extends. The first inclination angle θ may be the acute angle.

The pattern portion PPP may refer to a set of the plurality of protrusion portions PP. Since the protrusion portions PP having a certain structure are arranged at intervals in the second direction DR2 in the optical film OL, a specific pattern may be formed.

When viewed in a cross-section (or a transverse cross-section), as the second portion PP-2 of the protrusion portions PP is placed on the first portion PP-1 in a shape that is bent to have an inclination angle with respect to the first direction DR1, light incident on the optical film in the first direction DR1 may be refracted and emitted. The first portion may include a same material as the second portion and may have a same refractive index as the second portion. The first portion and the second portion, which have a same refractive index as each other, may refract and emit the light passing through the protrusion portions due to the structural feature of the first portion and the second portion, which have the bent shape with an internal angle therebetween.

When viewed in the cross-section, a length W1DS of the lower surface of the first portion PP-1 (i.e., a length in the second direction DR2 in FIG. 7) may be smaller than a length L1 of a side surface (or a height or length in the first direction DR1) of the first portion PP-1. The length L1 of the side surface of the first portion PP-1 may refer to the length of the longer side between the parallel sides of the trapezoidal shape in the cross-section. In an embodiment, the length W1DS of the lower surface of the first portion PP-1 is smaller than the length L1 of the side surface of the first portion PP-1, such that the light incident on the optical film OL may be converged, and thus, a light path may be set effectively.

When viewed in the cross-section, a length W2DS of a lower surface of the second portion PP-2 may be smaller than a length L2 of a side surface of the second portion PP-2. Since the second portion PP-2 has the rectangular shape when viewed in the cross-section, the length W2DS of the lower surface of the second portion PP-2 may be the same as a length of an upper surface of the second portion PP-2. In an embodiment, the length W2DS of the lower surface of the second portion PP-2 is smaller than the length L2 of the side surface of the second portion PP-2, such that the light incident on the optical film OL may be converged, and thus, the light path may be set effectively.

When viewed in the cross-section, a ratio of the length L2 of the side surface of the second portion PP-2 to the length L1 of the side surface of the first portion PP-1 may be in a range from about 1:1 to about 10:1. When the ratio of the length L2 of the side surface of the second portion PP-2 to the length L1 of the side surface of the first portion PP-1 falls outside this range, the path of the light incident into the optical film may not be effectively refracted. in an embodiment, for example, the ratio of the length L2 of the side surface of the second portion PP-2 to the length L1 of the side surface of the first portion PP-1 may be in a range from about 2:1 to about 8:1.

When viewed in the cross-section, a sum of the length L1 of the side surface of the first portion PP-1 and the length L2 of the side surface of the second portion PP-2 may be greater than or equal to about 1 μm and smaller than or equal to about 50 μm. When the sum of the length L1 of the side surface of the first portion PP-1 and the length L2 of the side surface of the second portion PP-2 falls outside this range, the light may not be effectively refracted. In an embodiment, for example, the sum of the length L1 of the side surface of the first portion PP-1 and the length L2 of the side surface of the second portion PP-2 may be greater than or equal to about 5 μm and smaller than or equal to about 40 μm.

When viewed in the cross-section, the separation distance Wp in the second direction DR2 between the protrusion portions PP may be greater than or equal to about 0.5 μm and smaller than or equal to about 5 μm. When the separation distance Wp in the second direction DR2 between the protrusion portions PP is greater than or equal to about 0.5 μm and smaller than or equal to about 5 μm, the optical film OL may have high optical properties. In an embodiment, for example, the separation distance Wp in the second direction DR2 between the protrusion portions PP may be greater than or equal to about 1 μm and smaller than or equal to about 4 μm.

When viewed in the cross-section, the first inclination angle θ may be in a range from about 1° to about 60°. The first inclination angle θ may be adjusted according to a desired direction in which the light is to be refracted. The base portion BS may have the flat or curved shape, and the first inclination angle θ of each of the protrusion portions may be either identical or different from one another in the optical film OL. In such an embodiment where the first inclination angle θ is in the range from about 1° to about 60°, the optical film OL may condense the light based on the emission direction of the light, and thus, the optical film OL may have high optical properties. In an embodiment, for example, the first inclination angle θ may be in a range from about 2°to about 45°.

In such an embodiment, since the protrusion portions PP have the bent shape by the first inclination angle θ in the optical film OL, the protrusion portions PP may refract the light provided from the upper or lower surface of the optical film OL. Accordingly, as the electronic device ED includes the optical film OL, the direction to which the image from the display module DM or the light is provided may be changed, and thus, a display quality of the electronic device may be improved.

The protrusion portions PP of the optical film OL may have the shape that is bent once by the first inclination angle θ, which is defined as a specific acute angle, and may not have a shape that is bent multiple times or a shape that is continuously curved.

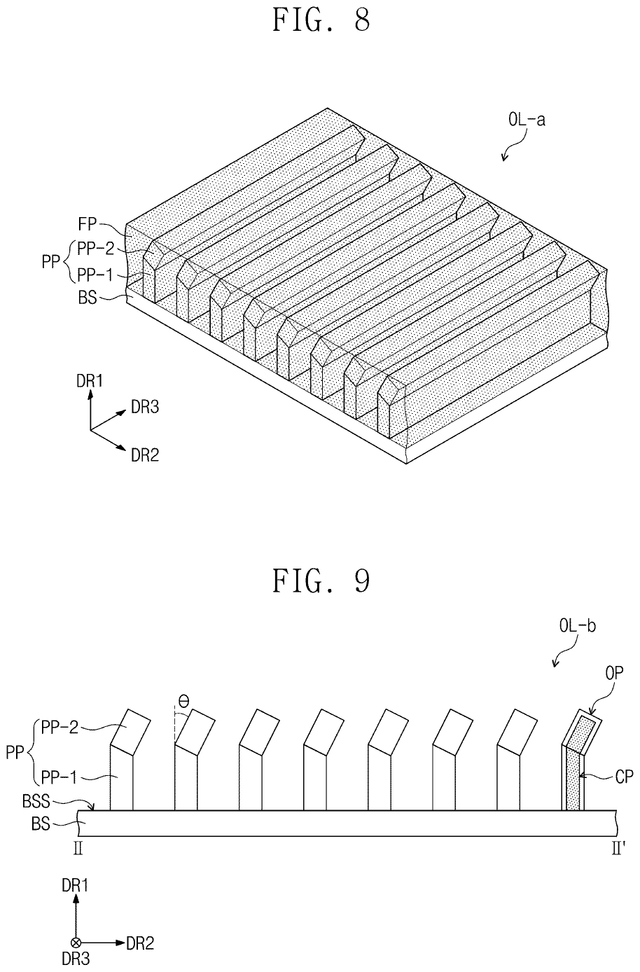

Hereinafter, optical films OL-a, OL-b, OL-c, and OL-d according to embodiments of the present disclosure will be described with reference to FIGS. 8 to 11. In describing the embodiments shown in FIGS. 8 to 11, any repetitive detailed description of the same or like element as those described above with reference to FIGS. 2A to 7 will be omitted, and descriptions will focus primarily on differences.

FIG. 8 is a perspective view of the optical film OL-a according to an embodiment of the present disclosure.

Referring to FIG. 8, an embodiment of the optical film OL-a may further include a filling portion FP filled in a space between a plurality of protrusion portions PP. The optical film OL-a may further include the filling portion FP compared to the optical film OL described with reference to FIGS. 5 to 7. The filling portion FP may be in contact with a base portion BS.

The filling portion FP may have a third refractive index. The third refractive index of the filling portion FP may be the same as or different from a first refractive index of

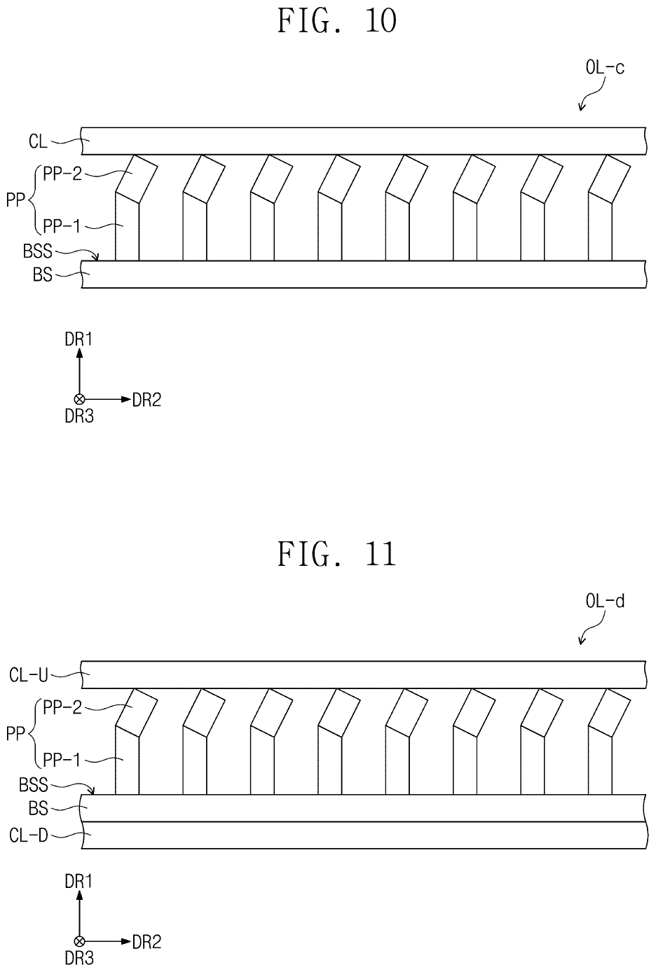

the protrusion portions PP. In addition, in an embodiment where the optical film OL-a further includes a cover layer CL (refer to FIG. 10) in addition to the filling portion FP as described later, the third refractive index of the filling portion FP may be the same as or different from a second refractive index of the cover layer CL (refer to FIG. 10).

The filling portion FP may include a transparent material. The filling portion FP may be filled in the space between the protrusion portions to cushion impacts caused by an external pressure applied to the optical film OL and may refract the light.

FIG. 9 is a cross-sectional view of the optical film OL-b according to an embodiment of the present disclosure.

Referring to FIG. 9, an embodiment of the optical film OL-b may include a plurality of protrusion portions PP, each of the protrusion portions PP may include an outer portion OP and a core portion CP surrounded by the outer portion OP, and the core portion CP may be filled with air. Since the core portion CP is filled with air having a refractive index of 1.00, the light provided from the display module DM may be refracted and directed toward the front of the electronic device ED due to the difference in refractive index between the outer portion and the core portion and the structural features of the optical film having the bent shape. Thus, the electronic device may have improved viewing angle characteristics such as high front luminance characteristics.

FIG. 10 is a cross-sectional view of the optical film OL-c according to an embodiment of the present disclosure. FIG. 11 is a cross-sectional view of the optical film OL-d according to an embodiment of the present disclosure.

In an embodiment, as shown in FIGS. 10 and 11, the optical film OL-c may further include the cover layer CL disposed at at least one selected from upper and lower sides of a base portion BS. Referring to FIG. 10, in an embodiment, the optical film OL-c may

include the cover layer CL disposed at the upper side of the base portion BS. In an embodiment where a cover layer CL is disposed at the upper side of a base portion BS, protrusion portions PP may be disposed between the base portion BS and the cover layer CL. Referring to FIG. 11, in another embodiment, the optical film OL-d may include cover layers CL-U and CL-D respectively disposed above and below a base portion BS. In another embodiment, although not shown in figures, the optical film may include a cover layer CL disposed only under the base portion BS.

In an embodiment where the optical film OL-c further includes the cover layer CL, the protrusion portions PP may have the first refractive index, and the cover layer CL may have the second refractive index different from the first refractive index. Materials for the cover layer CL should not be particularly limited, and the cover layer CL may include a transparent material. In such an embodiment, since the cover layer CL has the second refractive index, the cover layer CL may refract light refracted by the protrusion portions PP, or the light refracted by the cover layer CL may be refracted by the protrusion portions PP, and thus, the viewing angle characteristics of the electronic device ED may be improved.

In an embodiment where the optical film OL-c further includes the cover layer CL, a difference between the first refractive index of the protrusion portions PP and the second refractive index of the cover layer CL of the optical film OL may be greater than or equal to about 0.1 and smaller than or equal to about 2. In an embodiment, for example, where the

optical film OL-c further includes the cover layer CL, the difference between the first refractive index and the second refractive index may be greater than or equal to about 0.3 and smaller than or equal to about 1.5.

An embodiment of the optical film OL, OL-a, OL-b, OL-c, or OL-d described with reference to FIGS. 5 to 11 may be included in an electronic device according to an embodiment.

Referring back to FIGS. 2A and 3, an embodiment of the electronic device ED may include the main display surface MDS and at least one sub-display surface SDS for providing the image to the direction different from that of the main display surface MDS. The

electronic device ED may include the display module DM, the optical film OL disposed on the display module DM, and the window WM disposed on the optical film OL. The optical film OL may include the base portion BS forming at least one of upper and lower surfaces of the optical film OL and the protrusion portions PP disposed on the base portion BS. Each of the protrusion portions PP may include the first portion PP-1 extending in the first direction DR1 parallel to the thickness direction (or the first direction DR1) of the base portion BS and the second portion PP-2 connected to the first portion PP-1 and extending at the first inclination angle θ with respect to the first direction DR1, and the first inclination angle θ may be the acute angle.

The main display surface MDS may refer to a primary area of the screen where the user primarily runs applications and where basic content is displayed on the electronic device ED. In an embodiment of the electronic device ED, the main display surface MDS may be a display surface corresponding to the upper display module portion DMT. The main display surface MDS may be a flat surface.

The Sub-display Surface SDS May Correspond to an Edge of the Screen, a Curved portion, or an additional display surface other than the main display surface MDS, which serves as an auxiliary screen, and the sub-display surface SDS may be considered an extension of the main display surface. In an embodiment of the electronic device ED, the sub-display surface SDS may be a display surface corresponding to the side display module portions DMS-1 to DMS-4.

According to an embodiment of the electronic device ED, the optical film OL may be located corresponding to the main display surface MDS and the sub-display surface SDS. Referring to FIGS. 3 and 4, according to an embodiment of the electronic device ED, the upper optical film OLT may be located corresponding to the main display surface MDS, and the side optical films OLS-1 to OLS-4 may be located corresponding to the sub-display

surface SDS. In such an embodiment, the first inclination angles θ, the separation distances Wp in the second direction DR2 of the protrusion portions PP, the lengths W1DS of the lower

surface of the first portion PP-1, the lengths L1 of the side surface of the first portion PP-1, the lengths W2DS of the lower surface of the second portion PP-2, and the lengths L2 of the side surface of the second portion PP-2 in the optical films OLT and OLS-1 to OLS-4 may be the same or different from one another.

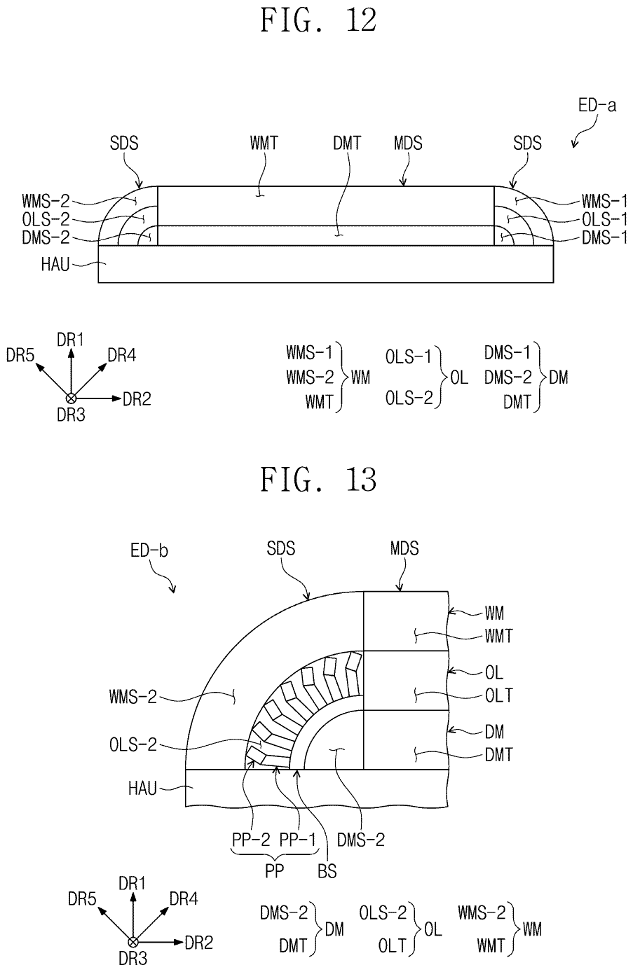

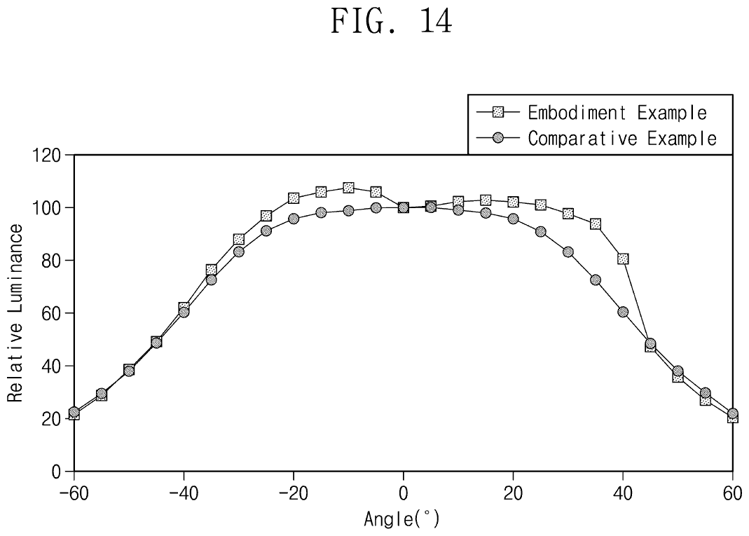

FIG. 12 is a cross-sectional view of an electronic device ED-a according to an embodiment of the present disclosure, and FIG. 13 is an enlarged cross-sectional view of a portion of an electronic device ED-b according to an embodiment of the present disclosure. FIG. 13 is a cross-sectional view of a portion of the electronic device ED-b taken along line I-I′ of FIG. 3.

According to an embodiment of the electronic device ED-a, an optical film OL may be located corresponding to at least one sub-display surface SDS. Referring to FIG. 12, the optical film may not be disposed on an upper display module portion DMT that is a main display surface MDS, and side optical films OLS-1 and OLS-2 may be respectively located corresponding to a first side display module portion DMS-1 and a second side display module portion DMS-2, which serve as a sub-display surface SDS. In such an embodiment, light provided toward the first direction DR1 from the upper display module portion DMT may be displayed as an image without any viewing angle control, and light paths of lights provided toward the fourth direction DR4 and the fifth direction DR5 from the side display module portions DMS-1 and DMS-2 may be changed toward the main display surface MDS through the viewing angle control by the side optical films OLS-1 and OLS-2. Accordingly, the luminance in the front direction may be improved, and a color difference between the front and side surfaces may be reduced, thereby improving the viewing angle characteristics.

In an embodiment where the side optical films OLS-1 and OLS-2 are located corresponding to plural sub-display surfaces SDS in the electronic device ED-a, the first inclination angles θ, the separation distances Wp in the second direction DR2 of the protrusion portions PP, the lengths W1DS of the lower surface of the first portion PP-1, the lengths L1 of

the side surface of the first portion PP-1, the length W2DS of the lower surface of the second portion PP-2, and the lengths L2 of the side surface of the second portion PP-2, which are described with reference to FIG. 7, in the side optical films OLS-1 and OLS-2 may be the same as or different from one another.

Referring to FIG. 13, in an embodiment, a sub-display surface SDS of the electronic device ED-b may have a curved surface convex to the fifth direction DR5 in which a second side display module portion DMS-2 provides an image. Accordingly, the viewing angle control characteristics such as luminance improvement and color difference reduction may be achieved on a main display surface MDS.

Referring to FIG. 13, in an embodiment, a base portion BS of an optical film OL arranged corresponding to the sub-display surface SDS in the electronic device ED-b may have a curved shape corresponding to the curved surface of the sub-display surface SDS. The optical film OL of the electronic device ED-b may include an upper optical film OLT and a second side optical film OLS-2. In addition, different from the electronic device ED-b shown in FIG. 13, the optical film OL may include only a side optical film corresponding to the sub-display surface SDS. In an embodiment, for example, the optical film may not be disposed in a portion corresponding to the main display surface MDS.

In an embodiment of the electronic device ED-b, the second side display module portion DMS-2 corresponding to the sub-display surface SDS may have a curved shape, and the base portion BS of the optical film OL may have a curved shape corresponding to the curved shape of the second side display module portion DMS-2. In such an embodiment, in protrusion portions PP disposed on one base portion BS, first inclination angles θ, separation distances Wp in the second direction DR2 of the protrusion portions PP, lengths W1DS of the lower surface of the first portion PP-1, lengths L1 of the side surface of the first portion PP-1, length W2DS of the lower surface of the second portion PP-2, and lengths L2 of the side surface of the second portion PP-2 may be the same as or different from one another, which are described with reference to FIG. 7. Accordingly, the viewing angle control characteristics such as luminance improvement and color difference reduction may be achieved on the main display surface MDS. However, the shape of the base portion BS should not be limited thereto or thereby, and the base portion BS may have the curved shape or a flat shape. FIG. 13 shows only a portion of an embodiment of the electronic device ED-b where the electronic device ED-b includes a plurality of sub-display surfaces SDS, the optical film OL may include side optical films respectively corresponding to the sub-display surfaces SDS. Each of the side optical films may include the protrusion portions including the base portion having a curved shape corresponding to a shape of the side display module portion and a second portion disposed on the base portion and bent in a direction toward the main display surface.

Referring to FIG. 13, in an embodiment of the second portion PP-2 of each of the protrusion portions PP may extend toward the front direction in the electronic device ED-b. Therefore, the image provided by the sub-display surface SDS may be refracted and directed toward the main display surface MDS compared to a case where the second side optical film OLS-2 does not exist.

According to a conventional electronic device that does not include an optical film to change a light path, a main display surface and a sub-display surface may provide images in different main directions, and therefore a portion with lower luminance is observed at or near a boundary between the main display surface and the sub-display surface compared to the main direction in which the image is provided. That is, most of the light is provided in

a direction perpendicular to a normal line of the display surface. Accordingly, from the perspective of a user viewing images in the front direction, the luminance between the main display surface and the sub-display surface is not uniform, and a color difference occurs. In addition, a dark area appears at the boundary between the main display surface and the sub-display surface, and a visual discontinuity caused by the luminance non-uniformity between the main display surface and the sub-display surface occurs.

As described herein, the optical film according to embodiments of the present disclosure may include protrusion portions having the bent portion that changes the traveling direction of the light and may refract the light to the main display surface direction, and thus, the display quality of the electronic device may be improved. In addition, since the electronic device according to embodiments of the present disclosure may include the optical film having the protrusion portions to change the light path, the luminance non-uniformity between the main display surface and the sub-display surface may be improved, and the color difference may be reduced, thereby improving the viewing angle characteristics. In addition, as the luminance non-uniformity between the main display surface and the sub-display surface is improved, the dark area appearing at the boundary between the main display surface and the sub-display surface may be reduced. Thus, the electronic device may have high display quality.

The optical film described with reference to FIGS. 5 to 11 may be included in an embodiment of the electronic device described with reference to FIG. 2B or 2C.

In an embodiment of the electronic device ED-1 shown in FIG. 2B, the optical film may overlap the entire display surface or only the edge of the display surface. In addition, the optical film may include the protrusion portions only in the area that overlaps the edge in the electronic device ED-1.

In an embodiment of the electronic device ED-2 shown in FIG. 2C, the optical film may overlap the entire display surface or only a folding portion that is a part of the display surface. The folding portion may refer to a portion of the display surface that is folded or unfolded about a folding axis. In addition, the optical film may include the protrusion portions only in the area that overlaps the folding portion in the electronic device ED-2.

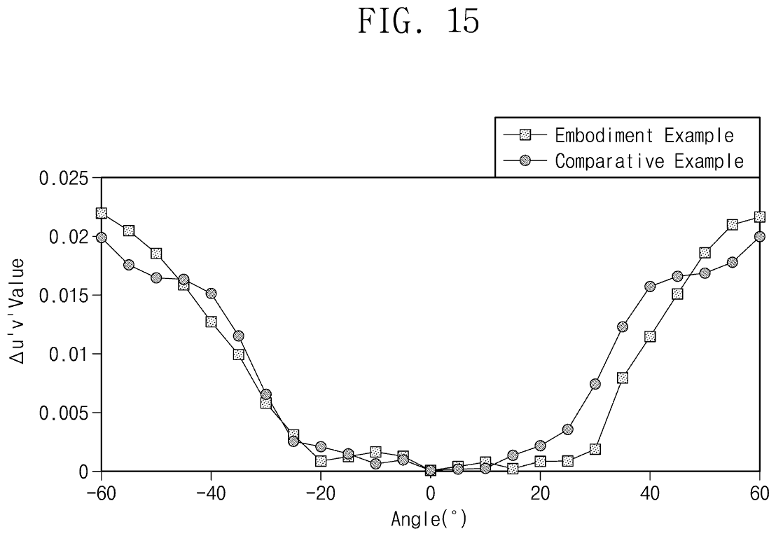

FIG. 14 is a graph showing results of evaluating a relative luminance as a function of a viewing angle of an electronic device according to an embodiment of the present disclosure and an electronic device according to a comparative example. FIG. 15 is a graph showing results of evaluating a color difference Δu′v′ as a function of a viewing angle of an electronic device according to an embodiment of the present disclosure and an electronic device according to a comparative example.

In FIGS. 14 and 15, the electronic device according to an example embodiment includes the optical film with the first inclination angle of about 10°, and the electronic device according to the comparative example does not include the optical film. After the electronic device of the embodiment example and the electronic device of the comparative example are set to provide the same image through their respective display modules, the relative luminance and the Δu′v′ value of the images provided by the electronic device of the embodiment example and the electronic device of the comparative example are measured at viewing angles ranging from −60° to 60°.

Referring to FIG. 14, it is observed that the relative luminance of the electronic device of the embodiment example is superior to that of the electronic device of the comparative example within the viewing angle range greater than or equal to −45° and smaller than −5° and the viewing angle range greater than or equal to 5° and smaller than 45°.

Accordingly, the optical film of the electronic device of the example embodiment may include the protrusion portions each having the bent shape, and the path of the light provided from the display module may be changed to a desired angle by the inclination angle of the bent portion of the protrusion portion. In addition, the luminance in a side viewing angle direction may be improved, so that a brighter image may be provided to the user, and sense of difference in image, which is caused by the luminance non-uniformity between the main display surface and the sub-display surface, may be reduced.

Referring to FIG. 15, the Δu′v′ value of the electronic device of the example embodiment is smaller than that of the electronic device of the comparative example in the viewing angle ranges of −45° to −10° and 10° to 45°, and thus, the color difference between the main display surface and the sub-display surface becomes small in the electronic device of the example embodiment. Accordingly, the electronic device of the embodiment example may have improved display quality.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An optical film comprising:
a base portion; and
a plurality of protrusion portions disposed on one surface of the base portion,
wherein each of the protrusion portions comprises:
a first portion extending in a first direction parallel to a thickness direction of the base portion; and
a second portion connected to the first portion and extending at a first inclination angle with respect to the first direction, wherein the first inclination angle is an acute angle.

2. The optical film of claim 1, wherein each of the first portion and the second portion has a stripe shape extending in one direction on a plane parallel to the one surface of the base portion.

3. The optical film of claim 1, further comprising a filling portion filled in a space between the protrusion portions.

4. The optical film of claim 1, wherein each of the protrusion portions comprises an outer portion and a core portion surrounded by the outer portion, and the core portion is filled with an air.

5. The optical film of claim 1, further comprising a cover layer disposed at at least one selected from upper and lower sides of the base portion,
wherein the protrusion portions have a first refractive index, and
the cover layer has a second refractive index different from the first refractive index.

6. The optical film of claim 5, wherein a difference between the first refractive index and the second refractive index is greater than or equal to about 0.1 and smaller than or equal to about 2.

7. An optical film comprising:
a base portion having a thickness in a first direction; and
a pattern portion comprising a plurality of protrusion portions disposed on one surface of the base portion and spaced apart from each other in a second direction different from the first direction,
wherein each of the protrusion portions comprises:
a first portion having a trapezoidal shape in a transverse cross-section and extending in the first direction; and
a second portion having a rectangular shape in the transverse cross-section, connected to the first portion, and extending at a first inclination angle with respect to a direction in which the first portion extends, wherein the first inclination angle is an acute angle.

8. The optical film of claim 7, wherein a length of a lower surface of the first portion is smaller than a length of a side surface of the first portion when viewed in the transverse cross-section.

9. The optical film of claim 7, wherein a length of a lower surface of the second portion connected to the first portion is smaller than a length of a side surface of the second portion in a direction away from the first portion when viewed in the transverse cross-section.

10. The optical film of claim 7, wherein a ratio of a length of a side surface of the second portion to a length of a side surface of the first portion is in a range from about 1:1 to about 10:1 when viewed in the transverse cross-section.

11. The optical film of claim 7, wherein a sum of a length of a side surface of the first portion and a length of a side surface of the second portion is greater than or equal to about 1 μm and smaller than or equal to about 50 μm when viewed in the transverse cross-section.

12. The optical film of claim 7, wherein a separation distance in the second direction between the protrusion portions is greater than or equal to about 0.5 μm and smaller than or equal to about 5 μm when viewed in the transverse cross-section.

13. The optical film of claim 7, wherein the first inclination angle is in a range from about 1° to about 60° when viewed in the transverse cross-section.

14. An electronic device comprising:
a display module comprising a main display surface and a sub-display surface which provides an image in a direction different from a direction of an image provided by the main display surface;
an optical film disposed on the display module; and
a window disposed on the optical film,
wherein the optical film comprises:
a base portion defining at least one selected from upper and lower surfaces of the optical film; and
a plurality of protrusion portions arranged on the base portion,
wherein each of the protrusion portions comprises:
a first portion extending in a first direction parallel to a thickness direction of the base portion; and
a second portion connected to the first portion and extending at a first inclination angle with respect to the first direction, wherein the first inclination angle is an acute angle.

15. The electronic device of claim 14, wherein the optical film is arranged to correspond to the sub-display surface.

16. The electronic device of claim 15, wherein the second portion of each of the protrusion portions extends from the first portion to the direction of the image provided by the main display surface.

17. The electronic device of claim 14, wherein the sub-display surface has a curved surface convex to the direction in which the image thereof is provided.

18. The electronic device of claim 17, wherein the base portion of the optical film, which is arranged to correspond to the sub-display surface, has a curved shape corresponding to the curved surface of the sub-display surface.

19. The electronic device of claim 14, wherein each of the first portion and the second portion has a stripe shape extending in one direction on a plane parallel to one surface of the base portion.

20. The electronic device of claim 14, further comprising at least one selected from a processor, a memory, and a power module.
